(19) United States
(12) Patent Application Publication
(10) Pub. No.: US 2024/0196648 A1
(43) Pub. Date: Jun. 13, 2024

(54) DISPLAY PANEL AND DISPLAY APPARATUS

(71) Applicant: Samsung Display Co., Ltd., Yongin-si (KR)

(72) Inventors: Dongsoo Kim, Yongin-si (KR); Joongsoo Moon, Yongin-si (KR); Hansol Kim, Yongin-si (KR); Jaeyong Lee, Yongin-si (KR); Sunbaek Hong, Yongin-si (KR)

(21) Appl. No.: 18/478,724

(22) Filed: Sep. 29, 2023

(30) Foreign Application Priority Data
Dec. 13, 2022 (KR) 10-2022-0174190

(51) Int. Cl. H10K 59/121; H10K 59/65

(52) U.S. Cl. CPC H10K 59/121; H10K 59/65

(57) ABSTRACT

A display panel includes: a substrate having a first area, a second area at least partially extending around a periphery of the first area, and a third area at least partially extending around a periphery of the second area; a first pixel portion in a portion of the first area that is adjacent to a boundary between the first area and the second area; and a second pixel portion nearer to a central portion of the first area than the first pixel portion is. A number of sub-pixels in the first pixel portion is less than a number of sub-pixels in the second pixel portion.

### CROSS-REFERENCE TO RELATED APPLICATION

This application claims priority to and the benefit of Korean Patent Application No. 10-2022-0174190, filed on Dec. 13, 2022, in the Korean Intellectual Property Office, the entire disclosure of which is incorporated herein by reference.

### BACKGROUND

### 1. Field

Aspects of embodiments of the present disclosure relate to a display panel and a display apparatus.

### 2. Description of the Related Art

Recently, the usage and applications of display apparatuses has diversified. Moreover, display apparatuses have become thinner and lighter, and thus, the usage thereof has increased.

As the area for displaying an image has been increased relative to the display apparatus overall, various functions connected to or associated with the display apparatuses have been added. As a method of adding various functions, research into a display apparatus including an area for displaying an image and for performing various functions has been continually conducted.

The area for displaying an image and for performing various functions may need to maintain a high transmittance with respect to light or sound to perform the functions. However, when high transmittance is maintained in the area for displaying an image and for performing various functions, the resolution of the display panel may be reduced.

### SUMMARY

Embodiments of the present disclosure include a display apparatus having high transmittance.

Additional aspects and features of the present disclosure will be set forth, in part, in the description that follows and, in part, will be apparent from the description or may be learned by practice of the described embodiments of the present disclosure.

According to an embodiment of the present disclosure, a display panel includes: a substrate having a first area, a second area extending at least partially around a periphery of the first area, and a third area extending at least partially around a periphery of the second area; a first pixel portion at least partially in a portion of the first area that is adjacent to a boundary between the first area and the second area; and a second pixel portion nearer to a central portion of the first area than the first pixel portion is. A number of sub-pixels in the first pixel portion is less than a number of sub-pixels in the second pixel portion.

The first pixel portion may include one first sub-pixel, one second sub-pixel, and two third sub-pixels.

The one first sub-pixel, the one second sub-pixel, and the two third sub-pixels may emit light of different colors from each other.

The display panel may further include a first pixel circuit portion in the second area and electrically connected to the first pixel portion, and the first pixel circuit portion may include one first sub-pixel circuit, one second sub-pixel circuit, and one third sub-pixel circuit.

The one first sub-pixel circuit, the one second sub-pixel circuit, and the one third sub-pixel circuit may be electrically connected to the one first sub-pixel, the one second sub-pixel, and the two third sub-pixels, respectively.

The one third sub-pixel circuit may be electrically connected to the two third sub-pixels.

The display panel may further include a third pixel portion in the second area, and the third pixel portion may include one first sub-pixel, one second sub-pixel, and one third sub-pixel.

The display panel may further include a second pixel circuit portion in the second area, and the second pixel circuit portion may include one first sub-pixel circuit, one second sub-pixel circuit, and three third sub-pixel circuits. At least one of the sub-pixel circuits in the second pixel circuit portion may be electrically connected to the third pixel portion.

The display panel may further include a fourth pixel portion in the second area, and the fourth pixel portion may include one first sub-pixel, one second sub-pixel, and three third sub-pixels.

The one first sub-pixel circuit and the one second sub-pixel circuit of the second pixel circuit portion may be electrically connected to the one first sub-pixel and the one second sub-pixel of the third pixel portion, respectively, and at least one of the three third sub-pixel circuits of the second pixel circuit portion may be electrically connected to the one third sub-pixel of the third pixel portion.

The one first sub-pixel circuit, the one second sub-pixel circuit, and the three third sub-pixel circuits of the second pixel circuit portion may be electrically connected to the one first sub-pixel, the one second sub-pixel, and the three third sub-pixels of the fourth pixel portion, respectively.

The second pixel portion may include two first sub-pixels, two second sub-pixels, and four third sub-pixels.

The display panel may further include a third pixel circuit portion in the second area and electrically connected to the second pixel portion, and the third pixel circuit portion may include one first sub-pixel circuit, one second sub-pixel circuit, and two third sub-pixel circuits.

The one first sub-pixel circuit and the one second sub-pixel circuit of the third pixel circuit portion may be electrically connected to the two first sub-pixels and the two second sub-pixels of the second pixel portion, respectively, and the two third sub-pixel circuits of the third pixel circuit portion may be electrically connected to the two third sub-pixels of the second pixel portion, respectively.

The display panel may further include a fifth pixel portion in the second area and on the third pixel circuit portion, and the fifth pixel portion may include one first sub-pixel, one second sub-pixel, and two third sub-pixels.

The display panel may further include a fourth pixel circuit portion in the second area and electrically connected to the fifth pixel portion, and the fourth pixel circuit portion may include one first sub-pixel circuit, one second sub-pixel circuit, and two third sub-pixel circuits.

The display panel may further include a sixth pixel portion in the second area and on the fourth pixel circuit portion, and the sixth pixel portion may include one first sub-pixel, one second sub-pixel, and two third sub-pixels.

The one first sub-pixel circuit, the one second sub-pixel circuit, and the two third sub-pixel circuits of the fourth pixel circuit portion may be electrically connected to the one first sub-pixel, the one second sub-pixel, and the two third sub-pixels of the fifth pixel portion, respectively.

The one first sub-pixel circuit, the one second sub-pixel circuit, and the two third sub-pixel circuits of the fourth pixel circuit portion may be electrically connected to the one first sub-pixel, the one second sub-pixel, and the two third sub-pixels of the sixth pixel portion, respectively.

According to an embodiment of the present disclosure, a display apparatus includes: a display panel; and a component arranged below the display panel. The display panel includes a substrate having a first area, a second area extending at least partially around a periphery of the first area, and a third area extending at least partially around a periphery of the second area, a first pixel portion at least partially in a portion of the first area that is adjacent to a boundary between the first area and the second area, and a second pixel portion nearer to a central portion of the first area than the first pixel portion is. A number of sub-pixels in the first pixel portion is less than a number of sub-pixels in the second pixel portion, and the component overlaps the first area.

### BRIEF DESCRIPTION OF THE DRAWINGS

The above and other aspects and features of the present disclosure will be more apparent from the following description, taken in conjunction with the accompanying drawings, in which:

FIG. 1 is a schematic view of a display apparatus according to an embodiment;

FIG. 2 is a schematic cross-sectional view of a display apparatus according to an embodiment;

FIG. 3 is a schematic equivalent circuit diagram of a pixel circuit electrically connected to a display element according to an embodiment;

FIG. 4 is a schematic plan view of a display panel according to an embodiment;

FIGS. 5A to 5C are schematic plan views of a first area and a second area of a display panel according to an embodiment; and

FIGS. 6 and 7 are schematic cross-sectional views taken along the lines I-I′ and III-III′ and the lines II-II′ and IV-IV′ of FIG. 5C, respectively, according to an embodiment.

### DETAILED DESCRIPTION

Reference will now be made, in detail, to embodiments, examples of which are illustrated in the accompanying drawings. In this regard, the described embodiments may have different forms and should not be construed as being limited to the descriptions set forth herein. Accordingly, embodiments are merely described below, by referring to the figures, to explain aspects and features of the present description.

While the present disclosure may be variously modified and may have alternative forms, embodiments thereof are shown by way of example in the drawings and will herein be described in detail. Aspects and features of the present disclosure, and methods the provide the same, will become apparent by referring to the drawings and embodiments described in detail below. However, the present disclosure is not limited to the embodiments disclosed hereinafter and may be realized in various forms.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

When a certain embodiment may be implemented differently, a specific process order may be performed differently from the described order. For example, two consecutively described processes may be performed substantially at the same time or performed in an order opposite to the described order.

The x-axis, the y-axis, and the z-axis of any coordinate system described herein are not limited to three axes of the rectangular coordinate system and may be interpreted in a broader sense. For example, the x-axis, the y-axis, and the z-axis may be perpendicular to one another, or may represent different directions that are not perpendicular to one another.

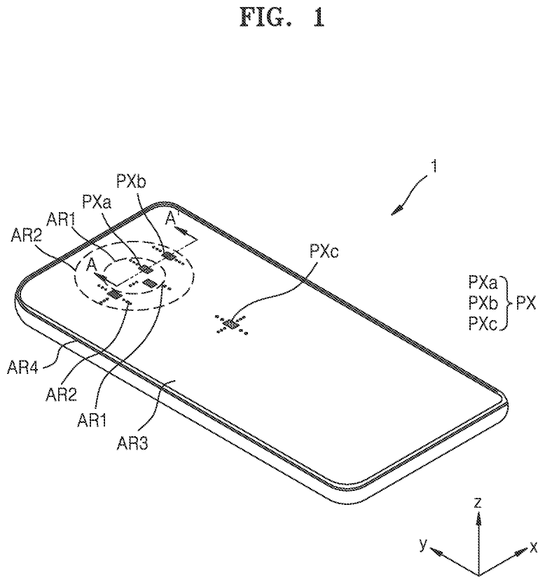

FIG. 1 is a schematic view of a display apparatus 1 according to an embodiment.

Referring to FIG. 1, the display apparatus 1 may display (e.g., may be configured to display) an image. The display apparatus 1 may include sub-pixels PX. The sub-pixel PX may be defined as an area in which a display element emits light. A plurality of sub-pixels P may be provided in the display apparatus 1. The plurality of sub-pixels PX may each emit light to display an image. According to an embodiment, the sub-pixels PX may include a sub-pixel PXa arranged in a first area AR1, a sub-pixel PXb arranged in a second area AR2, and a sub-pixel PXc arranged in a third area AR3.

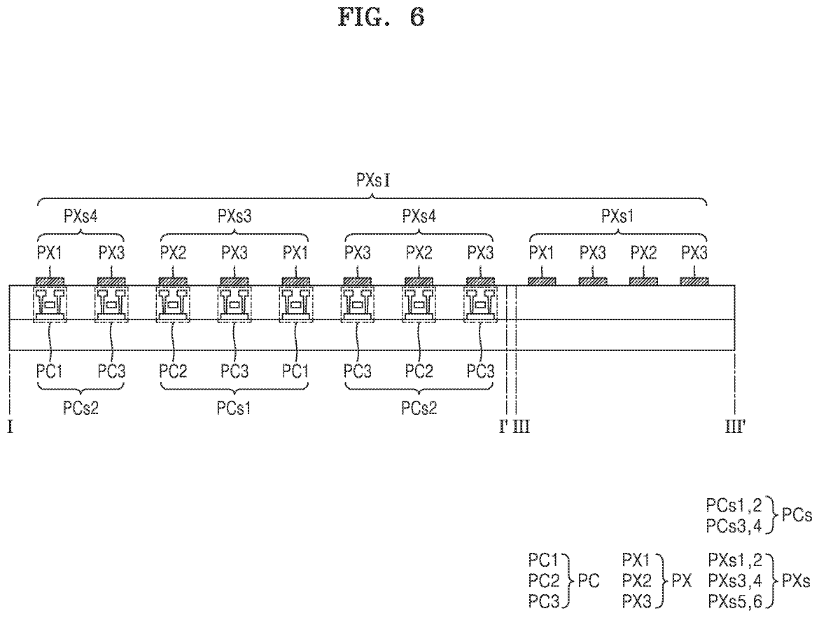

According to an embodiment, the sub-pixels PX may include a first sub-pixel PX1 (see, e.g., FIG. 6), a second sub-pixel PX2 (see, e.g., FIG. 6), and a third sub-pixel PX3 (see, e.g., FIG. 6). The first to third sub-pixels PX1 to PX3 may each emit light of a different wavelength band. The first to third sub-pixels PX1 to PX3 may each emit a different color of light. For example, the first sub-pixel PX1 may emit a red color of light, the second sub-pixel PX2 may emit a blue color of light, and the third sub-pixel PX3 may emit a green color of light.

The display apparatus 1 may have the first area AR1, the second area AR2, the third area AR3, and a fourth area AR4. The sub-pixels PX may be arranged in the first to third areas AR1 to AR3. Thus, the first to third areas AR1 to AR3 may be display areas at where an image is displayed. As described above, the sub-pixels PXa, PXb, and PXc may be arranged in the first to third areas AR1 to AR3, respectively. The sub-pixel PX may not be arranged in the fourth area AR4. Thus, the fourth area AR4 may be a non-display area at where an image is not displayed (e.g., the fourth area AR4 may be a bezel area).

At least one of the first and second areas AR1 and AR2 may overlap a component and may be an area in which the sub-pixel PX is arranged. For example, the first area AR1 may overlap the component and may be the area in which the sub-pixel PX is arranged. In some embodiments, both of the first and second areas AR1 and AR2 may overlap the component and may be the areas in which the sub-pixel PX is arranged. According to an embodiment, the sub-pixels PXa and PXb may be arranged in the first and second areas AR1 and AR2, respectively. Thus, the first and second areas AR1 and AR2 may be areas at where an image is displayed, and the component may be arranged below the first and second areas AR1 and AR2.

At least one of the first and second areas AR1 and AR may overlap the component. Thus, the first area AR1 and/or the second area AR2 of the display apparatus 1 may have to have a high light transmittance and/or a high sound transmittance. For example, the light transmittance of the display apparatus 1 in the first area AR1 and/or the second area AR2 may be greater than or equal to about 10%, greater than or equal to about 25%, greater than or equal to about 40%, greater than or equal to about 50%, greater than or equal to about 85%, or greater than or equal to about 90%. According to an embodiment, the light transmittance of the display apparatus 1 in the first area AR1 may be higher than the light transmittance of the display apparatus 1 in the second area AR2.

According to an embodiment, the display apparatus 1 may include at least one first area AR1. For example, the display apparatus 1 may include one first area AR1 or a plurality of first areas AR1.

According to an embodiment, the second area AR2 may at least partially surround (e.g., may at least partially surround in a plan view or may at least partially extend around a periphery of) the first area AR1. In some embodiments, for example, as illustrated in FIG. 1, the second area AR2 may entirely surround the first area AR1. In other embodiments, however, the second area AR2 may be arranged at a side of the first area AR1. For example, the first area AR1 and the second area AR2 may be arranged in parallel with each other in a first direction (e.g., in the x direction or the −x direction in FIG. 1). In other embodiments, the first area AR1 and the second area AR2 may be arranged in parallel with each other in a second direction (e.g., in the y direction or the −y direction in FIG. 1). In yet other embodiments, the second area AR2 may be arranged at both sides of the first area AR1.

According to an embodiment, the first area AR1 and the second area AR2 may be arranged at an upper side of the display apparatus 1. However, the present disclosure is not limited thereto, and in other embodiments, the first area AR1 and the second area AR2 may be arranged at a lower side, a right side, or a left side of the display apparatus 1.

According to an embodiment, at least one of the first area AR1 and the second area AR2 may have various shapes, such as a circular shape, an oval shape, or a polygonal shape, such as a quadrangular shape, a star shape, a diamond shape, etc., in a plan view (e.g., the in x-y plane of FIG. 1). FIG. 1 illustrates an embodiment in which each of the first and second areas AR1 and AR2 has a circular shape. However, the present disclosure is not limited thereto, and in another embodiment, each of the first and second areas AR1 and AR2 may have a quadrangular shape.

The third area AR3 may at least partially surround the first area AR1 and/or the second area AR2. According to an embodiment, and as illustrated in FIG. 1, the second area AR2 may entirely surround the first area AR1, and the third area AR3 may entirely surround the second area AR2. A resolution of the display apparatus 1 in the third area AR3 may be higher than or equal to a resolution of the display apparatus 1 in the first area AR1.

The fourth area AR4 may at least partially surround the third area AR3. According to an embodiment, the fourth area AR4 may entirely surround the third area AR3. As described above, the sub-pixel PX may not be arranged in the fourth area AR4.

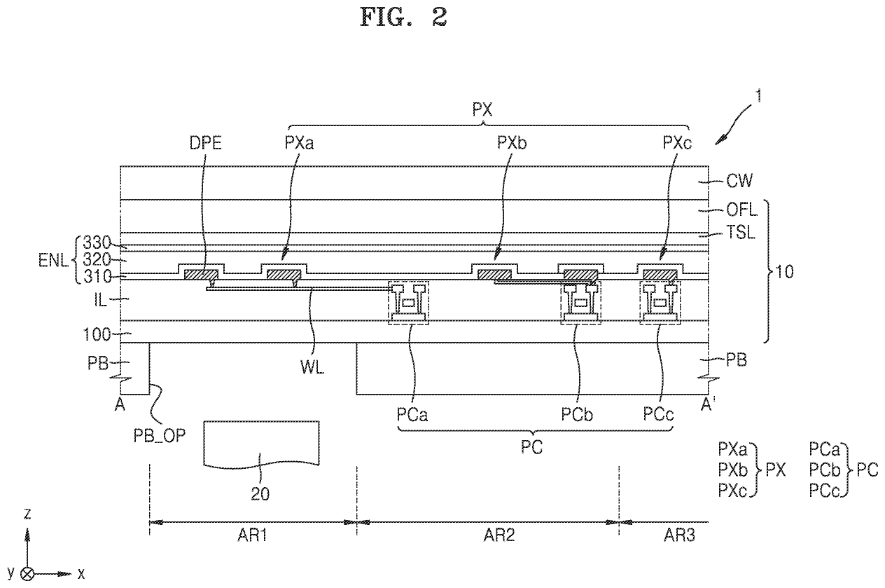

FIG. 2 is a schematic cross-sectional view of the display apparatus 1 taken along the line A-A′ of FIG. 1 according to an embodiment.

Referring to FIG. 2, the display apparatus 1 may include a display panel 10, a panel protection member PB, a component 20, and a cover window CW. The display panel 10 may include a substrate 100, an insulating layer IL, a pixel circuit PC, a display element DPE, an encapsulation layer ENL, a touch sensor layer TSL, and an optical functional layer OFL.

The display apparatus 1 may have the first area AR1, the second area AR2, and the third area AR3. The display apparatus 1 may include the substrate 100, and thus, the substrate 100 may have the first to third areas AR1 to AR3. For example, the first to third areas AR1 to AR3 may be defined on the substrate 100. Hereinafter, an embodiment in which the substrate 100 has the first to third areas AR1 to AR3 will be primarily described in detail.

The substrate 100 may include an insulating material, such as glass, quartz, and polymer resins. The substrate 100 may be a rigid substrate or a flexible substrate, which may be bent, folded, or rolled.

The insulating layer IL and the pixel circuit PC may be arranged on the substrate 100. The insulating layer IL may insulate the components of the display panel 10 from each other. The insulating layer IL may include at least one of an organic material and an inorganic material.

The pixel circuit PC may be electrically connected to the display element DPE and may drive the display element DPE. The pixel circuit PC may be arranged in the insulating layer IL. The pixel circuit PC may include a pixel circuit PCa electrically connected to the sub-pixel PXa arranged in the first area AR1, a pixel circuit PCb electrically connected to the sub-pixel PXb arranged in the second area AR2, and a pixel circuit PCc electrically connected to the sub-pixel PXc arranged in the third area AR3. The pixel circuit PC may be arranged in the second area AR2 and the third area AR3. The pixel circuit PCa electrically connected to the sub-pixel PXa arranged in the first area AR1 and the pixel circuit PCb electrically connected to the sub-pixel PXb arranged in the second area AR2 may be arranged in the second area AR2. Also, the pixel circuit PCc electrically connected to the sub-pixel PXc arranged in the third area AR3 may be arranged in the third area AR3. According to an embodiment, the pixel circuit PC may not be arranged in the first area AR1. Thus, a transmittance (e.g., light transmittance) of the display panel 10 in the first area AR1 may be relatively higher than a transmittance of the display panel 10 in the second area AR2 and the third area AR3.

The display element DPE may be arranged on the insulating layer IL. According to an embodiment, the display element DPE may include an organic light-emitting diode including an organic emission layer. In another embodiment, the display element DPE may include a light-emitting diode. A size of the light-emitting diode may be micro-scale or nano-scale. For example, the light-emitting diode may include a micro-light-emitting diode. In other embodiments, the light-emitting diode may include a nanorod-light-emitting diode. The nanorod light-emitting diode may include GaN. According to an embodiment, a color conversion layer may be arranged on the nanorod light-emitting diode, and the color conversion layer may include quantum dots. In other embodiments, the display element DPE may include a quantum dot light-emitting diode including a quantum dot emission layer. In other embodiments, the display element DPE may include an inorganic light-emitting diode including an inorganic semiconductor. Hereinafter, an embodiment in which the display element DPE includes an organic light-emitting diode will be described as an example.

The display panel 10 may include a plurality of display elements DPE. The plurality of display elements DPE may be arranged in the first area AR1, the second area AR2, and the third area AR3. According to an embodiment, the display element DPE may emit light to realize the sub-pixel PX. For example, the display element DPE arranged in the first area AR1 may emit light to realize the sub-pixel PXa arranged in the first area AR1. The display element DPE arranged in the second area AR2 may emit light to realize the sub-pixel PXb arranged in the second area AR2. Also, the display element DPE arranged in the third area AR3 may emit light to realize the sub-pixel PXc arranged in the third area AR3. Thus, the display apparatus 1 may display an image in the first to third areas AR1 to AR3.

According to an embodiment, the pixel circuit PCa electrically connected to the display element DPE arranged in the first area AR1 may be arranged in the second area AR2. The plurality of display elements DPE arranged in the first area AR1 may be electrically connected to one pixel circuit PCa arranged in the second area AR2. The plurality of display elements DPE may emit light by using a small number of pixel circuits PCa arranged in the second area AR2, and thus, the transmittance of the first area AR1 may be increased.

The pixel circuit PCa arranged in the second area AR2 and the display elements DPE arranged in the first area AR1 may be electrically connected to each other through a line WL. The line WL may extend from the second area AR2 to the first area AR1. Thus, the line WL may be arranged in the first area AR1 and the second area AR2.

The line WL may include a transparent conductive material. For example, the line WL may include a transparent conductive oxide (TCO). The line WL may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO).

According to an embodiment, the plurality of display elements DPE arranged in the second area AR2 may be electrically connected to one pixel circuit PCb arranged in the second area AR2. Thus, the plurality of display elements DPE arranged in the second area AR2 may emit light by using a small number of pixel circuits PCb arranged in the second area AR2.

The encapsulation layer ENL may cover the display element DPE. According to an embodiment, the encapsulation layer ENL may include at least one inorganic encapsulation layer and at least one organic encapsulation layer. The at least one inorganic encapsulation layer may include one or more inorganic materials from among Al₂O₃, TiO₂, Ta₂O₅, ZnO, SiO₂, SiNₓ, and SiON. The at least one organic encapsulation layer may include a polymer-based material. The polymer-based material may include acryl-based resins, epoxy-based resins, polyimide, polyethylene, etc. According to an embodiment, the at least one organic encapsulation layer may include acrylate.

According to an embodiment, the encapsulation layer ENL may include a first inorganic encapsulation layer 310, an organic encapsulation layer 320, and a second inorganic encapsulation layer 330 that are sequentially stacked. The first inorganic encapsulation layer 310 and the second inorganic encapsulation layer 330 may prevent or reduce the penetration of impurities, such as moisture, etc., into the organic encapsulation layer 320 and/or the display element DPE.

In some embodiments, the encapsulation layer ENL may have a structure in which the substrate 100 and a sealing substrate, which is a transparent member, are coupled via a sealing member so that an inner space between the substrate 100 and the sealing substrate is sealed. Here, an absorbent or a filler may be provided in the inner space. The sealing member may be a sealant. In some embodiments, the sealing member may include a material hardened by a laser beam. For example, the sealing member may include frit. For example, the sealing member may include urethane-based resins, epoxy-based resins, or acryl-based resins, which are organic sealants, or silicone, which is an inorganic sealant. The urethane-based resins may include, for example, urethane acrylate, etc. The acryl-based resins may include, for example, butyl acrylate, ethyl hexyl acrylate, etc. The sealing member may include a material hardened by heat.

The touch sensor layer TSL may obtain coordinate information based on an external input, for example, a touch event. The touch sensor layer TSL may include a touch electrode and touch lines connected to the touch electrode. The touch sensor layer TSL may sense an external input based on a magnetic capacitance method or a mutual capacitance method.

The touch sensor layer TSL may be arranged on the encapsulation layer ENL. According to an embodiment, the touch sensor layer TSL may be arranged directly above the encapsulation layer ENL. In such an embodiment, an adhesive layer, such as an optically clear adhesive (OCA), may not be arranged between the touch sensor layer TSL and the encapsulation layer ENL. In other embodiments, the touch sensor layer TSL may be separately formed on a touch substrate and then may be coupled onto the encapsulation layer ENL through an adhesive layer, such as the OCA.

The optical functional layer OFL may include a reflection prevention layer. The reflection prevention layer may reduce reflectivity of light (e.g., external light) incident to the display apparatus 1 from the outside. According to an embodiment, the optical functional layer OFL may include a polarization film. In some embodiments, the optical functional layer OFL may include a filter plate including a black matrix and color filters.

The cover window CW may be arranged on the display panel 10. The cover window CW may protect the display panel 10. The cover window CW may include at least one of glass, sapphire, and plastic. The cover window CW may include, for example, ultra-thin glass (UTG) or colorless polyimide (CPI).

The panel protection member PB may be arranged below the substrate 100. The panel protection member PB may support and protect the substrate 100. According to an embodiment, the panel protection member PB may have an opening PB_OP defined therein overlapping the first area AR1. For example, the panel protection member PB may have the opening PB_OP overlapping the first area AR1. In some embodiments, the opening PB_OP in the panel protection member PB may overlap the first area AR1 and the second area AR2. The panel protection member PB may include polyethylene terephthalate or polyimide.

The component 20 may be arranged below the display panel 10. According to an embodiment, the component 20 may be arranged on the opposite side of the display panel 10 with respect to the cover window CW. According to an embodiment, the component 20 may overlap the first area AR1. In some embodiments, the component 20 may overlap the first area AR1 and the second area AR2.

The component 20 may include a camera using (e.g., configured to receive) infrared rays or visible rays and may include a capturing device. In some embodiments, the component 20 may include a solar battery, a flash device, an illuminance sensor, a proximity sensor, an iris sensor, etc. In some embodiments, the component 20 may be configured to receive sound (e.g., may be a microphone). To reduce or minimize limiting the functionality of the component 20, the pixel circuit PC may not be arranged in the first area AR1, below which the component 20 is arranged. For example, a pixel circuit PCa (e.g., the first sub-pixel circuit PX1) configured to drive the display element DPE arranged in the first area AR1 may not be arranged in the first area AR1 and may be arranged in the second area AR2. Thus, the transmittance (e.g., the light transmittance) of the display panel 10 in the first area AR1 may be higher than the transmittance (e.g., the light transmittance) of the display panel 10 in the second area AR2.

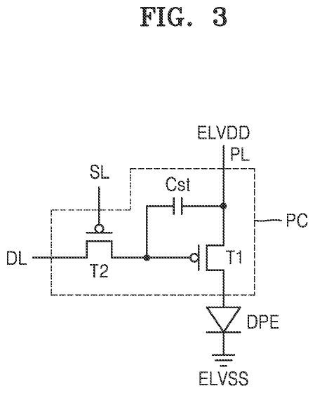

FIG. 3 is a schematic equivalent circuit diagram of the pixel circuit PC electrically connected to the display element DPE according to an embodiment.

Referring to FIG. 3, the pixel circuit PC may include a driving thin-film transistor T1, a switching thin-film transistor T2, and a storage capacitor Cst.

The switching thin-film transistor T2 may be electrically connected to each of a scan line SL and a data line DL and may be configured to transmit a data signal (e.g., a data voltage) input through the data line DL to the driving thin-film transistor T1 in response to a scan signal (e.g., a switching voltage) input through the scan line SL. The storage capacitor Cst may be electrically connected to the switching thin-film transistor T2 and a driving voltage line PL and may be configured to store a voltage corresponding to a difference between a voltage received from the switching thin-film transistor T2 and a driving voltage ELVDD supplied to the driving voltage line PL.

The driving thin film transistor T1 may be electrically connected to each of the driving voltage line PL and the storage capacitor Cst and may be configured to control a driving current flowing from the driving voltage line PL through the display element DPE according to a value of the voltage stored in the storage capacitor Cst. The display element DPE may emit light having a brightness (e.g., a predetermined brightness) according to the driving current. An opposite electrode of the display element DPE may receive a common voltage ELVSS.

FIG. 3 illustrates an embodiment in which the pixel circuit PC includes two thin-film transistors and one storage capacitor. However, the pixel circuit PC may include three or more thin-film transistors.

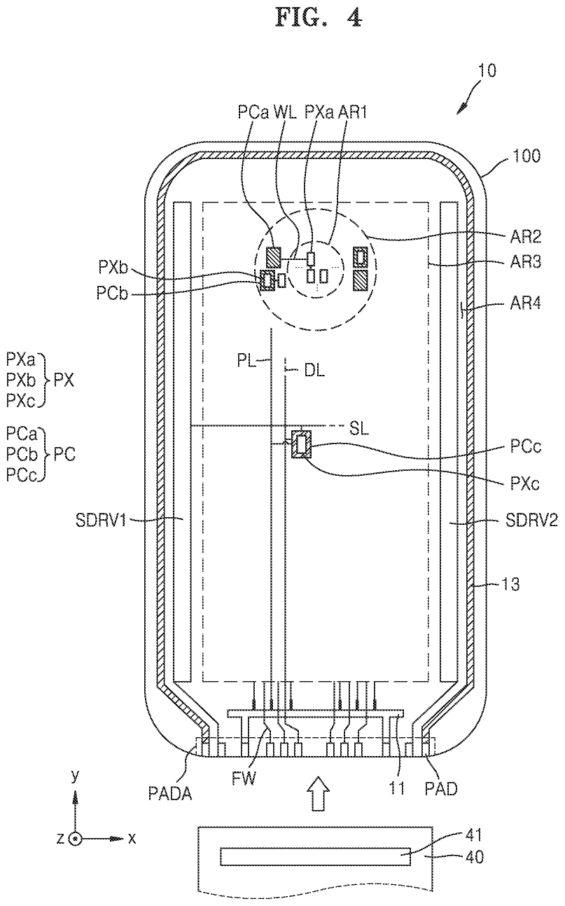

FIG. 4 is a schematic plan view of the display panel 10 according to an embodiment. With respect to FIG. 4, the same reference symbols as used in FIG. 1 denote the same components, and thus, will not be described again.

Referring to FIG. 4, the display panel 10 may include the substrate 100, the pixel circuit PC, and the sub-pixel PX. According to an embodiment, the substrate 100 may have the first area AR1, the second area AR2, the third area AR3, and the fourth area AR4. As illustrated in FIG. 4, the second area AR2 may entirely surround the first area AR1. The third area AR3 may at least partially surround the first area AR1 and/or the second area AR2. The fourth area AR4 may at least partially surround the third area AR3.

The pixel circuit PC may include the pixel circuit PCa electrically connected to the sub-pixel PXa arranged in the first area AR1, the pixel circuit PCb electrically connected to the sub-pixel PXb arranged in the second area AR2, and the pixel circuit PCc electrically connected to the sub-pixel PXc arranged in the third area AR3. The pixel circuit PCa electrically connected to the sub-pixel PXa arranged in the first area AR1 and the pixel circuit PCb electrically connected to the sub-pixel PXb arranged in the second area AR2 may both be arranged in the second area AR2. Also, the pixel circuit PCc electrically connected to the sub-pixel PXc arranged in the third area AR3 may be arranged in the third area AR3. The pixel circuit PC (e.g., all pixel circuits PC) may not be arranged in the first area AR1.

The sub-pixel PX may be realized by a display element, such as an organic light-emitting diode. The display apparatus 1 may include a plurality of the sub-pixels PX. The sub-pixels PX may include the sub-pixel PXa arranged in the first area AR1, the sub-pixel PXb arranged in the second area AR2, and the sub-pixel PXc arranged in the third area AR3.

According to an embodiment, the pixel circuit PCa electrically connected to the sub-pixel PXa arranged in the first area AR1 may be arranged in the second area AR2. According to an embodiment, the sub-pixel PXa arranged in the first area AR1 may be electrically connected to the pixel circuit PCa arranged in the second area AR2 through the line WL. According to an embodiment, any one of a plurality of sub-pixels PXa arranged in the first area AR1 may be electrically connected to another of the plurality of sub-pixels PXa arranged in the first area AR1. In such an embodiment, the one of the plurality of sub-pixels PXa arranged in the first area AR1 and the other of the plurality of sub-pixels PXa arranged in the first area AR1 may be connected to one pixel circuit PCa arranged in the second area AR2 and may likewise emit light.

According to an embodiment, the pixel circuit PCb electrically connected to the sub-pixel PXb arranged in the second area AR2 may be arranged in the second area AR2. According to an embodiment, the sub-pixel PXb arranged in the second area AR2 may be electrically connected to the pixel circuit PCb arranged in the second area AR2. According to an embodiment, any one of a plurality of sub-pixels PXb arranged in the second area AR2 may be electrically connected to another of the plurality of sub-pixels PXb arranged in the second area AR2 through a line WL. In such an embodiment, the one of the plurality of sub-pixels PXb arranged in the second area AR2 and the other of the plurality of sub-pixels PXb arranged in the second area AR2 may be connected to one pixel circuit PCb arranged in the second area AR2 and may likewise emit light.

According to an embodiment, the pixel circuit PCc electrically connected to the sub-pixel PXc arranged in the third area AR3 may be arranged in the third area AR3. The sub-pixel PXc arranged in the third area AR3 may overlap the pixel circuit PCc electrically connected to the sub-pixel PXc.

A plurality of sub-pixels PX may be provided, and the plurality of sub-pixels PX may emit light to display an image. According to an embodiment, each of the sub-pixels PXa, PXb, and PXc arranged in the first to third areas AR1 to AR3, respectively, may be provided in a multiple number. Each of the plurality of sub-pixels PXa, the plurality of sub-pixels PXb, and the plurality of sub-pixels PXc arranged in the first to third areas AR1 to AR3, respectively, may display one image or may display separate images.

According to an embodiment, the resolution of the display panel 10 in the first area AR1 and/or the second area AR2 may be less than or equal to the resolution of the display panel 10 in the third area AR3. For example, the resolution of the display panel 10 in the first area AR1 and/or the second area AR2 may be about ½, ⅜, ⅓, ¼, 2/9, ⅛, 1/9, or 1/16 of the resolution of the display panel 10 in the third area AR3.

The fourth area AR4 may be a non-display area in which the sub-pixels PX are not arranged. A first scan driving circuit SDRV1, a second scan driving circuit SDRV2, a pad PAD, a driving voltage supply line 11, and a common voltage supply line 13 may be arranged in the fourth area AR4.

Any one of the first scan driving circuit SDRV1 and the second scan driving circuit SDRV2 may be configured to apply a scan signal to the pixel circuit PC through the scan line SL. According to an embodiment, the first scan driving circuit SDRV1 and the second scan driving circuit SDRV2 may be arranged on the opposite side to each other with the third area AR3 therebetween. According to an embodiment, any one of the plurality of sub-pixels PX may receive the scan signal from the first scan driving circuit SDRV1, and another of the plurality of sub-pixels PX may receive the scan signal from the second scan driving circuit SDRV2.

The pad PAD may be arranged in a pad area PADA at a side of the fourth area AR4. The pad PAD may not be covered by an insulating layer to be exposed and connected to a display circuit board 40. A display driver 41 may be arranged on the display circuit board 40.

The display driver 41 may be configured to generate signals to transmit to the first scan driving circuit SDRV1 and the second scan driving circuit SDRV2. The display driver 41 may generate a data signal, and the generated data signal may be transmitted to the pixel circuit PC through a fan-out wire FW and a data line DL connected to the fan-out wire FW.

The display driver 41 may supply the driving voltage ELVDD (see, e.g., FIG. 3) to the driving voltage supply line 11 and supply the common voltage ELVSS (see, e.g., FIG. 3) to the common voltage supply line 13. The driving voltage ELVDD may be supplied to the pixel circuit PC through the driving voltage line PL connected to the driving voltage supply line 11, and the common voltage ELVSS may be supplied to the opposite electrode of the display element connected to the common voltage supply line 13.

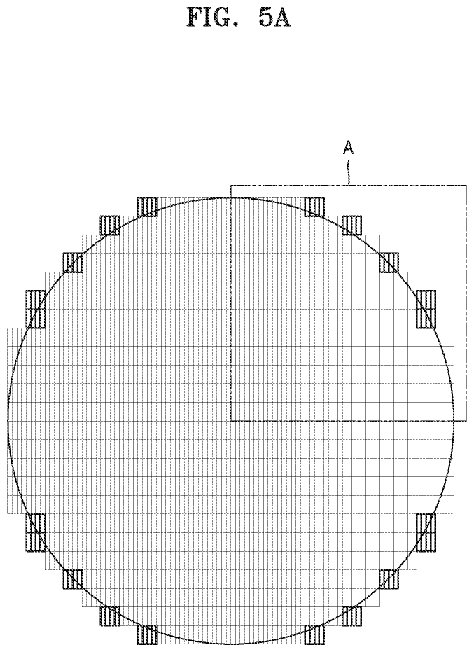

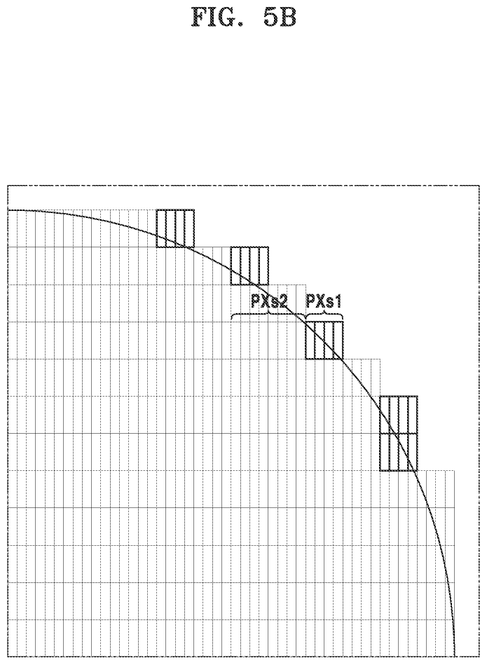

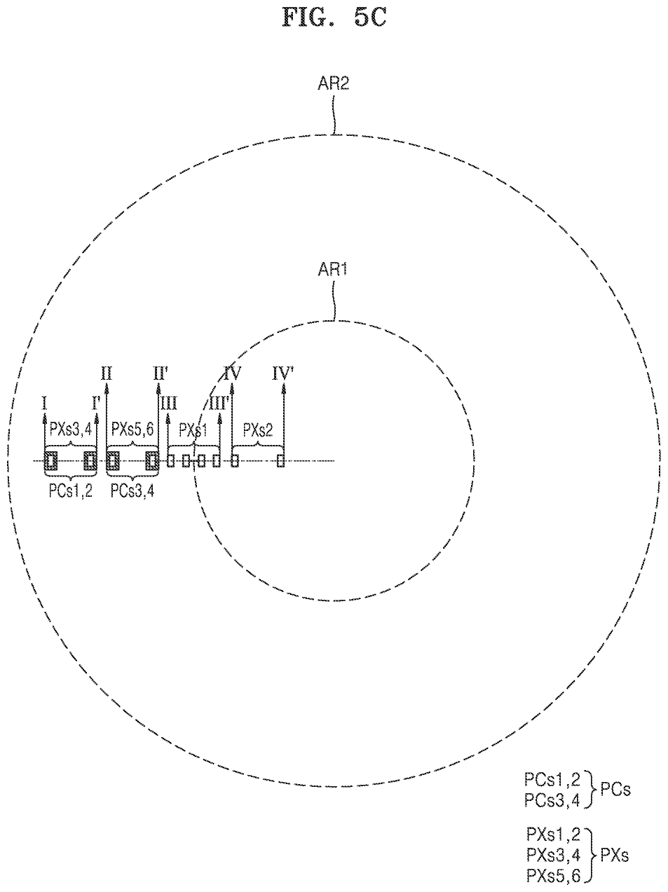

FIGS. 5A to 5C are schematic plan views of the first area AR1 and the second area AR2 of the display panel 10 according to an embodiment. In detail, FIG. 5A is a schematic plan view of pixel portions PXs arranged in the first area AR1 of the display panel 10. FIG. 5B is an enlarged view of the area A in FIG. 5A. FIG. 5C is a detailed layout of the pixel portions PXs and pixel circuit portions PCs arranged in the first area AR1 and the second area AR2 of the display panel 10. The pixel portions PXs may include the plurality of sub-pixels PX, and the pixel circuit portions PCs may include the plurality of pixel circuits PC.

Referring to FIGS. 5A, 5B, and 5C, the display panel 10 may have a first area AR1 and a second area AR2. According to an embodiment, the pixel portions PXs may be arranged in the first and second areas AR1 and AR2. The pixel circuit portions PCs for enabling light emission of the pixel portions PXs arranged in the first and second areas AR1 and AR2 may be arranged in (e.g., may be arranged only in) the second area AR2. The first area AR1 may overlap the component 20 below the display panel 10, and thus, to improve the light transmittance of the first area AR1, the pixel circuit portions PCs configured to drive light emission of the pixel portions PXs arranged in the first area AR1 may not be arranged in the first area AR1. For example, the pixel circuit portions PCs (e.g., a first pixel circuit portion PCs1 or a third pixel circuit portion PCs3) for driving light emission of the pixel portions PXs (e.g., a first pixel portion PXs1 and a second pixel portion PXs2) arranged in the first area AR1 may be arranged in the second area AR2.

The pixel portions PXs may be arranged in the first area AR1 of the display panel 10. The pixel portions PXs arranged in the first area AR1 may include the first pixel portion PXs1 and the second pixel portion PXs2. The first area AR1 of the display panel 10 may be entirely surrounded by the second area AR2, and the first area AR1 may have a circular shape. The first pixel portion PXs1 may be arranged in at least a portion of the first area AR1, and the portion of the first area AR1 may be adjacent to a boundary between the first area AR1 and the second area AR2 of the display panel 10. For example, the first pixel portion PXs1 may be arranged in a portion of the first area AR1 that is adjacent to the second area AR2. However, the present disclosure is not limited thereto. One or more of a plurality of sub-pixels included in the first pixel portion PXs1 may be arranged in at least a portion of the second area AR2 beyond (or outside of) the boundary of the first area AR1 and the second area AR2. The second pixel portion PXs2 may be arranged to be more adjacent to (e.g., to be nearer to) a central portion of the first area AR1 than the first pixel portion PXs1 is. For example, the second pixel portion PXs2 may be arranged in a portion of the first area AR1 that is not adjacent to the second area AR2. For example, the second pixel portion PXs2 may be arranged to be adjacent to a center of the circular shape of the first area AR1.

According to an embodiment, the first pixel portion PXs1 may include four sub-pixels PX. For example, the first pixel portion PXs1 may include one first sub-pixel PX1, one second sub-pixel PX2, and two third sub-pixels PX3. The second pixel portion PXs2 may include eight sub-pixels. For example, the second pixel portion PXs2 may include two first sub-pixels PX1, two second sub-pixels PX2, and four third sub-pixels PX3. The first to third sub-pixels PX1 to PX3 may each emit a different color of light. For example, the first sub-pixel PX1 may emit a red color of light. The second sub-pixel PX2 may emit a blue color of light. Also, the third sub-pixel PX3 may emit a green color of light.

The number of sub-pixels included in the first pixel portion PXs1 arranged in at least the portion of the first area AR1 that is adjacent to the boundary of the first and second areas AR1 and AR2 may be less than the number of sub-pixels included in the second pixel portion PXs2 arranged to be adjacent to the central portion of the first area AR1. Because the first pixel portion PXs1 arranged in at least the portion of the first area AR1 that is adjacent to the boundary of the first and second areas AR1 and AR2 may have a decreased (or relatively small) area, the circular shape of the first area AR1 may be smooth. For example, the area of the first pixel portion PXs1 arranged in at least the portion of the first area AR1 that is adjacent to the boundary of the first and second areas AR1 and AR2 may be less than an area of the second pixel portion PXs2 arranged to be adjacent to the central portion of the first area AR1, and thus, the circular shape of the first area AR1 may be smooth.

The second area AR2 may be arranged to entirely surround the first area AR1. The pixel portions PXs may be arranged in the second area AR2. The pixel portions PXs arranged in the second area AR2 may include a third pixel portion PXs3, a fourth pixel portion PXs4, a fifth pixel portion PXs5, and a sixth pixel portion PXs6. Each of the third to sixth pixel portions PXs3 to PXs6 may include a plurality of first sub-pixels PX1, a plurality of second sub-pixels PX2, and a plurality of third sub-pixels PX3. The number of sub-pixels included in each of the third to sixth pixel portions PXs3 to PXs6 arranged in the second area AR2 may be different from each other. This will be described in more detail below.

The pixel circuit portions PCs may be arranged in the second area AR2. Each of the pixel circuit portions PCs may include a plurality of first sub-pixel circuits PC1, a plurality of second sub-pixel circuits PC2, and a plurality of third sub-pixel circuits PC3. The first sub-pixel circuit PC1 may drive light emission of the first sub-pixel PX1. For example, the first sub-pixel circuit PC1 may be electrically connected to the first sub-pixel PX1. The second sub-pixel circuit PC2 may drive light emission of the second sub-pixel PX2. For example, the second sub-pixel circuit PC2 may be electrically connected to the second sub-pixel PX2. The third sub-pixel circuit PC3 may drive light emission of the third sub-pixel PX3. For example, the third sub-pixel circuit PC3 may be electrically connected to the third sub-pixel PX3.

A first pixel circuit portion PCs1, a second pixel circuit portion PCs2, a third pixel circuit portion PCs3, and a fourth pixel circuit portion PCs4 may be arranged in the second area AR2. The first and third pixel circuit portions PCs1 and PCs3 may respectively drive light emission of the first and second pixel portions PXs1 and PXs2 arranged in the first area AR1. For example, the first and third pixel circuit portions PCs1 and PCs3 may respectively be electrically connected to the first and second pixel portions PXs1 and PXs2 arranged in the first area AR1. The second pixel circuit portion PCs2 may drive light emission of the third pixel portion PXs3 and the fourth pixel portion PXs4 arranged in the second area AR2. For example, the second pixel circuit portion PCs2 may be electrically connected to the third pixel portion PXs3 and the fourth pixel portion PXs4 arranged in the second area AR2. The fourth pixel circuit portion PCs4 may drive light emission of the fifth pixel portion PXs5 and the sixth pixel portion PXs6 arranged in the second area AR2. For example, the fourth pixel circuit portion PCs4 may be electrically connected to the fifth pixel portion PXs5 and the sixth pixel portion PXs6 arranged in the second area AR2. However, the present disclosure is not limited thereto.

According to an embodiment, the third pixel portion PXs3 and the fourth pixel portion PXs4 may be arranged on the first pixel circuit portion PCs1 and the second pixel circuit portion PCs2 arranged in the second area AR2. For example, the third pixel portion PXs3 and the fourth pixel portion PXs4 may be arranged in the second area AR2 to overlap the first pixel circuit portion PCs1 and the second pixel circuit portion PCs2, respectively. Also, the fifth pixel portion PXs5 and the sixth pixel portion PXs6 may be arranged on the third pixel circuit portion PCs3 and the fourth pixel circuit portion PCs4 arranged in the second area AR2. For example, the fifth pixel portion PXs5 and the sixth pixel portion PXs6 may be arranged in the second area AR2 to overlap the third pixel circuit portion PCs3 and the fourth pixel circuit portion PCs4, respectively.

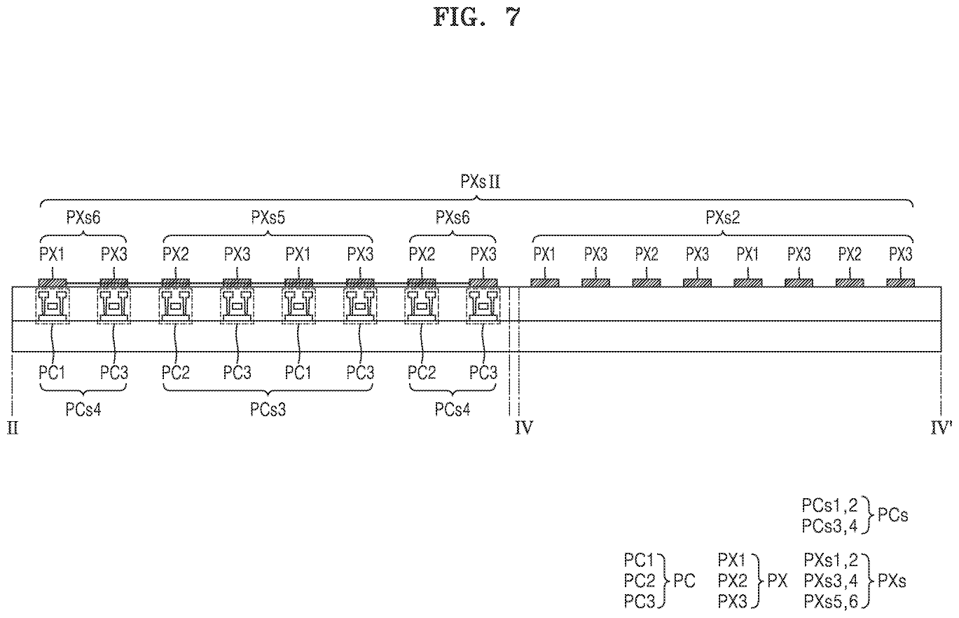

FIG. 6 is a schematic cross-sectional view taken along the lines I-I′ and III-III′ of FIG. 5 according to an embodiment. FIG. 7 is a schematic cross-sectional view taken along the lines II-II′ and IV-IV′ of FIG. 5 according to an embodiment. FIG. 6 schematically illustrates reduced unit pixel portion PXs I arranged throughout the first area AR1 and the second area AR2, and FIG. 7 schematically illustrates a basic unit pixel portion PXs II arranged throughout the first area AR1 and the second area AR2.

Referring to FIGS. 6 and 7, the basic unit pixel portion PXs II and the reduced unit pixel portion PXs I may be arranged in the first and second areas AR1 and AR2 of the display panel 10. Each of the basic unit pixel portion PXs II and the reduced unit pixel portion PXs I may include one pixel portion PXs arranged in the first area AR1 and two pixel portions PXs arranged in the second area AR2. The basic unit pixel portion PXs II may include the second pixel portion PXs2 arranged in the first area AR1 and the fifth pixel portion PXs5 and the sixth pixel portion PXs6 arranged in the second area AR2. The second pixel portion PXs2, the fifth pixel portion PXs5, and the sixth pixel portion PXs6 may include eight, four, and four sub-pixels PX, respectively. The basic unit pixel portion PXs II may include a total of 16 sub-pixels PX. The reduced unit pixel portion PXs I may include the first pixel portion PXs1 arranged in the first area AR1 and the third pixel portion PXs3 and the fourth pixel portion PXs4 arranged in the second area AR2. The first pixel portion PXs1, the third pixel portion PXs3, and the fourth pixel portion PXs4 may include four, three, and five sub-pixels PX, respectively. The reduced unit pixel portion PXs I may include a total of 12 sub-pixels PX. The number of sub-pixels PX arranged in the second area AR2 included in the basic unit pixel portion PXs II may be the same as the number of sub-pixels PX arranged in the second area AR2 included in the reduced unit pixel portion PXs I. The number of sub-pixels PX included in the basic unit pixel portion PXs II may be less than the number of sub-pixels PX included in the reduced unit pixel portion PXs I.

The first pixel portion PXs1 included in the reduced unit pixel portion PXs I may be arranged in at least a portion of (e.g., at least partially in) the first area AR1 adjacent to a boundary between the first area AR1 and the second area AR2. The second pixel portion PXs2 included in the basic unit pixel portion PXs II may be arranged to be more adjacent to (e.g., nearer to) a central portion of the first area AR1 than the first pixel portion PXs1 is. The number of sub-pixels PX included in the first pixel portion PXs1 arranged at a boundary portion between the first area AR1 and the second area AR2, that is, arranged in at least the portion of the first area AR1 that is adjacent to the boundary of the first and second areas AR1 and AR2 may be less than the number of sub-pixels PX included in the second pixel portion PXs2 arranged at the central (or more central) portion of the first area AR1. Thus, a circular shape of the first area AR1 may be more smoothly formed. For example, the number of sub-pixels PX included in the first pixel portion PXs1 arranged at the boundary portion between the first area AR1 and the second area AR2, that is, arranged in at least the portion of the first area AR1, that is adjacent to the boundary of the first and second areas AR1 and AR2 may be less than the number of sub-pixels PX included in the second pixel portion PXs2 arranged at the central portion of the first area AR1. Thus, an edge (or a curve) of the circular shape of the first area AR1 may be smoothly formed.

The basic unit pixel portion PXs II and the reduced unit pixel portion PXs I may emit light by using the pixel circuit portions PCs arranged in the second area AR2. For example, two pixel circuit portions PCs arranged in the second area AR2 may be electrically connected to the three pixel portions PXs included in each of the basic unit pixel portion PXs II and the reduced unit pixel portion PXs I. This will be described in more detail below.

Referring to FIG. 6, the reduced unit pixel portion PXs I may be arranged in the first and second areas AR1 and AR2 of the display panel 10. The reduced unit pixel portion PXs I may include three pixel portions PXs. The reduced unit pixel portion PXs I may include the first pixel portion PXs1 arranged in the first area AR1 and the third pixel portion PXs3 and the fourth pixel portion PXs4 arranged in the second area AR2. The first pixel portion PXs1, the third pixel portion PXs3, and the fourth pixel portion PXs4 may include four, three, and five sub-pixels PX, respectively. The reduced unit pixel portion PXs I may include a total of 12 sub-pixels PX.

According to an embodiment, the first pixel portion PXs1 of the reduced unit pixel portion PXs I may be arranged in the first area AR1. The first pixel portion PXs1 may include one first sub-pixel PX1, one second sub-pixel PX2, and two third sub-pixels PX3. The third pixel portion PXs3 of the reduced unit pixel portion PXs I may be arranged in the second area AR2. The third pixel portion PXs3 may include one first sub-pixel PX1, one second sub-pixel PX2, and one third sub-pixel PX3. The fourth pixel portion PXs4 of the reduced unit pixel portion PXs I may be arranged in the second area AR2. The fourth pixel portion PXs4 may include one first sub-pixel PX1, one second sub-pixel PX2, and three third sub-pixels PX3. As described above, the first to third sub-pixels PX1 to PX3 may emit different colors of light from each other. For example, the first sub-pixel PX1 may emit a red color of light, the second sub-pixel PX2 may emit a blue color of light, and the third sub-pixel PX3 may emit a green color of light.

According to an embodiment, the pixel circuit PC may include the first sub-pixel circuit PC1 driving light emission of the first sub-pixel PX1, the second sub-pixel circuit PC2 driving light emission of the second sub-pixel PX2, and the third sub-pixel circuit PC3 driving light emission of the third sub-pixel PX3. The first to third sub-pixel circuits PC1 to PC3 may be electrically connected to the first to third sub-pixels PX1 to PX3, respectively, and may drive light emission of the first to third sub-pixels PX1 to PX3, respectively.

According to an embodiment, the first pixel circuit portion PCs1 driving light emission of the first pixel portion PXs1 may be arranged in the second area AR2. The first pixel circuit portion PCs1 may be arranged to overlap the third pixel portion PXs3. The first pixel circuit portion PCs1 may include one first sub-pixel circuit PC1, one second sub-pixel circuit PC2, and one third sub-pixel circuit PC3. The first sub-pixel circuit PC1 of the first pixel circuit portion PCs1 may be electrically connected to one first sub-pixel PX1 of the first pixel portion PXs1. The first sub-pixel PX1 of the first pixel portion PXs1 may be electrically connected to the first sub-pixel circuit PC1 of the first pixel circuit portion PCs1 through a connection line. For example, the first sub-pixel circuit PC1 of the first pixel circuit portion PCs1 may drive light emission of the first sub-pixel PX1 of the first pixel portion PXs1. The second sub-pixel circuit PC2 of the first pixel circuit portion PCs1 may be electrically connected to the second sub-pixel PX2 of the first pixel portion PXs1. The second sub-pixel PX2 of the first pixel portion PXs1 may be electrically connected to the second sub-pixel circuit PC2 of the first pixel circuit portion PCs1 through a connection line. For example, the second sub-pixel circuit PC2 of the first pixel circuit portion PCs1 may drive light emission of the second sub-pixel PX2 of the first pixel portion PXs1. One third sub-pixel circuit PC3 of the first pixel circuit portion PCs1 may be electrically connected to the two third sub-pixels PX3 of the first pixel portion PXs1. The two third sub-pixels PX3 of the first pixel portion PXs1 may be electrically connected to one third sub-pixel circuit PC3 of the first pixel circuit portion PCs1 through a connection line. For example, one third sub-pixel circuit PC3 of the first pixel circuit portion PCs1 may drive light emission of the two third sub-pixels PX3 of the first pixel portion PXs1. However, the present disclosure is not limited thereto.

According to an embodiment, the second pixel circuit portion PCs2 may be arranged in the second area AR2. The second pixel circuit portion PCs2 may be arranged to overlap the fourth pixel portion PXs4. The second pixel circuit portion PCs2 may include one first sub-pixel circuit PC1, one second sub-pixel circuit PC2, and three third sub-pixel circuits PC3. One first sub-pixel circuit PC1 of the second pixel circuit portion PCs2 may be electrically connected to the first sub-pixel PX1 of the third pixel portion PXs3 and the first sub-pixel PX1 of the fourth pixel portion PXs4. One first sub-pixel circuit PC1 of the second pixel circuit portion PCs2 may be electrically connected to the first sub-pixel PX1 of the third pixel portion PXs3 and the first sub-pixel PX1 of the fourth pixel portion PXs4 through a connection line. For example, one first sub-pixel circuit PC1 of the second pixel circuit portion PCs2 may drive light emission of the first sub-pixel PX1 of the third pixel portion PXs3 and the first sub-pixel PX1 of the fourth pixel portion PXs4. One second sub-pixel circuit PC2 of the second pixel circuit portion PCs2 may be electrically connected to the second sub-pixel PX2 of the third pixel portion PXs3 and the second sub-pixel PX2 of the fourth pixel portion PXs4. One second sub-pixel circuit PC2 of the second pixel circuit portion PCs2 may be electrically connected to the second sub-pixel PX2 of the third pixel portion PXs3 and the second sub-pixel PX2 of the fourth pixel portion PXs4 through a connection line. For example, one second sub-pixel circuit PC2 of the second pixel circuit portion PCs2 may drive light emission of the second sub-pixel PX2 of the third pixel portion PXs3 and the second sub-pixel PX2 of the fourth pixel portion PXs4. At least one of three third sub-pixel circuits PC3 included in the second pixel circuit portion PCs2 may be electrically connected to not only the third sub-pixel PX3 of the fourth pixel portion PXs4 but also to the third sub-pixel PX3 of the third pixel portion PXs3. At least one of the three third sub-pixel circuits PC3 of the second pixel circuit portion PCs2 may be electrically connected to the third sub-pixel PX3 of the third pixel portion PXs3 and the third sub-pixel PX3 of the fourth pixel portion PXs4 through a connection line. For example, the at least one of the three third sub-pixel circuits PC3 of the second pixel circuit portion PCs2 may drive light emission of the third sub-pixel PX3 of the third pixel portion PXs3 and the third sub-pixel PX3 of the fourth pixel portion PXs4. However, the present disclosure is not limited thereto.

Referring to FIG. 7, the basic unit pixel portion PXs II may be arranged in the first and second areas AR1 and AR2 of the display panel 10. The basic unit pixel portion PXs II may include three pixel portions PXs. The basic unit pixel portion PXs II may include the second pixel portion PXs2 arranged in the first area AR1 and the fifth pixel portion PXs5 and the sixth pixel portion PXs6 arranged in the second area AR2. The second pixel portion PXs2, the fifth pixel portion PXs5, and the sixth pixel portion PXs6 may include eight, four, and four sub-pixels PX, respectively. The basic unit pixel portion PXs II may include a total of 16 sub-pixels PX.

According to an embodiment, the second pixel portion PXs2 of the basic unit pixel portion PXs II may be arranged in the first area AR1. The second pixel portion PXs2 may include two first sub-pixels PX1, two second sub-pixels PX2, and four third sub-pixels PX3. The fifth pixel portion PXs5 of the basic unit pixel portion PXs II may be arranged in the second area AR2. The fifth pixel portion PXs5 may include one first sub-pixel PX1, one second sub-pixel PX2, and two third sub-pixels PX3. The sixth pixel portion PXs6 of the basic unit pixel portion PXs II may be arranged in the second area AR2. The sixth pixel portion PXs6 may include one first sub-pixel PX1, one second sub-pixel PX2, and two third sub-pixels PX3.

According to an embodiment, the third pixel circuit portion PCs3 driving light emission of the second pixel portion PXs2 may be arranged in the second area AR2. The third pixel circuit portion PCs3 may be arranged to overlap the fifth pixel portion PXs5. The third pixel circuit portion PCs3 may include one first sub-pixel circuit PC1, one second sub-pixel circuit PC2, and two third sub-pixel circuits PC3. The first sub-pixel circuit PC1 of the third pixel circuit portion PCs3 may be electrically connected to the two first sub-pixels PX1 of the second pixel portion PXs2. The two first sub-pixels PX1 of the second pixel portion PXs2 may be electrically connected to one first sub-pixel circuit PC1 of the third pixel circuit portion PCs3 through a connection line. For example, one first sub-pixel circuit PC1 of the third pixel circuit portion PCs3 may drive light emission of the two first sub-pixels PX1 of the second pixel portion PXs2. The second sub-pixel circuit PC2 of the third pixel circuit portion PCs3 may be electrically connected to the two second sub-pixels PX2 of the second pixel portion PXs2. The two second sub-pixels PX2 of the second pixel portion PXs2 may be electrically connected to one second sub-pixel circuit PC2 of the third pixel circuit portion PCs3 through a connection line. For example, one second sub-pixel circuit PC2 of the third pixel circuit portion PCs3 may drive light emission of the two second sub-pixels PX2 of the second pixel portion PXs2. Also, each of the two third sub-pixel circuits PC3 of the third pixel circuit portion PCs3 may be electrically connected to two third sub-pixels PX3 of the second pixel portion PXs2. For example, one third sub-pixel circuit PC3 of the third pixel circuit portion PCs3 may be electrically connected to two third sub-pixels PX3 of the second pixel portion PXs2. The two third sub-pixels PX3 of the second pixel portion PXs2 may be electrically connected to one third sub-pixel circuit PC3 of the third pixel circuit portion PCs3 through a connection line. For example, one third sub-pixel circuit PC3 of the third pixel circuit portion PCs3 may drive light emission of the two third sub-pixels PX3 of the second pixel portion PXs2. The two third sub-pixel circuits PC3 of the third pixel circuit portion PCs3 may drive light emission of the four third sub-pixels PX3 of the second pixel portion PXs2.

According to an embodiment, the fourth pixel circuit portion PCs4 may be arranged in the second area AR2. The fourth pixel circuit portion PCs4 may be arranged to overlap the sixth pixel portion PXs6. The fourth pixel circuit portion PCs4 may include one first sub-pixel circuit PC1, one second sub-pixel circuit PC2, and two third sub-pixel circuits PC3. One first sub-pixel circuit PC1 of the fourth pixel circuit portion PCs4 may be electrically connected to the first sub-pixel PX1 of the sixth pixel portion PXs6 and the first sub-pixel PX1 of the fifth pixel portion PXs5. One first sub-pixel circuit PC1 of the fourth pixel circuit portion PCs4 may be electrically connected to the first sub-pixel PX1 of the sixth pixel portion PXs6 and the first sub-pixel PX1 of the fifth pixel portion PXs5 through a connection line. For example, one first sub-pixel circuit PC1 of the fourth pixel circuit portion PCs4 may drive light emission of the first sub-pixel PX1 of the sixth pixel portion PXs6 and the first sub-pixel PX1 of the fifth pixel portion PXs5. One second sub-pixel circuit PC2 of the fourth pixel circuit portion PCs4 may be electrically connected to the second sub-pixel PX2 of the sixth pixel portion PXs6 and the second sub-pixel PX1 of the fifth pixel portion PXs5. One second sub-pixel circuit PC2 of the fourth pixel circuit portion PCs4 may be electrically connected to the second sub-pixel PX2 of the sixth pixel portion PXs6 and the second sub-pixel PX2 of the fifth pixel portion PXs5 through a connection line. For example, one second sub-pixel circuit PC2 of the fourth pixel circuit portion PCs4 may drive light emission of the second sub-pixel PX2 of the sixth pixel portion PXs6 and the second sub-pixel PX2 of the fifth pixel portion PXs5. Each of the two third sub-pixel circuits PC3 of the fourth pixel circuit portion PCs4 may be electrically connected to the third sub-pixel PX3 of the sixth pixel portion PXs6 and the third sub-pixel PX3 of the fifth pixel portion PXs5. One third sub-pixel circuit PC3 of the fourth pixel circuit portion PCs4 may be electrically connected to the third sub-pixel PX3 of the sixth pixel portion PXs6 and the third sub-pixel PX3 of the fifth pixel portion PXs5 through a connection line. For example, one third sub-pixel circuit PC3 of the fourth pixel circuit portion PCs4 may drive light emission of the third sub-pixel PX3 of the sixth pixel portion PXs6 and the third sub-pixel PX3 of the fifth pixel portion PXs5. The two third sub-pixel circuits PC3 of the fourth pixel circuit portion PCs4 may drive light emission of the two third sub-pixel PX3 of the sixth pixel portion PXs6 and the two third sub-pixel PX3 of the fifth pixel portion PXs5. However, the present disclosure is not limited thereto.

The first area of the display panel may overlap the component. To improve the light transmittance of the first area, pixel circuits may not be arranged in the first area. However, to display an image in the first area, the pixel portions may be arranged in the first area.

The first area may have a circular shape. The pixel portions arranged in the first area may include eight sub-pixels. When the pixel portions including the eight sub-pixels are arranged in the first area, the circular shape of the first area may not be smooth (e.g., the circular shape may have jagged or step-like edges).

According to an embodiment, the number of sub-pixels included in the pixel portions arranged in a portion of the first area that is adjacent to a boundary between the first and second areas may be less than the number of sub-pixels included in the pixel portions arranged in a central (or more central) portion of the first area. The area of the pixel portions arranged at the boundary between the first and second areas may be reduced, and thus, the circular shape of the first area may be more smooth.

The descriptions above are primarily focused on a display apparatus, but the present disclosure is not limited thereto.

As described above, according to the one or more of the above embodiments, a display apparatus having improved light transmittance may be provided. However, the present disclosure is not limited thereto.

It should be understood that the embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims and their equivalents.

What is claimed is:

1. A display panel comprising:
a substrate having a first area, a second area at least partially extending around a periphery of the first area, and a third area at least partially extending around a periphery of the second area;
a first pixel portion in a portion of the first area that is adjacent to a boundary between the first area and the second area; and
a second pixel portion nearer to a central portion of the first area than the first pixel portion is, a number of sub-pixels in the first pixel portion being less than a number of sub-pixels in the second pixel portion.

2. The display panel of claim 1, wherein the first pixel portion comprises one first sub-pixel, one second sub-pixel, and two third sub-pixels.

3. The display panel of claim 2, wherein the one first sub-pixel, the one second sub-pixel, and the two third sub-pixels emit light of different colors from each other.

4. The display panel of claim 2, further comprising a first pixel circuit portion in the second area and electrically connected to the first pixel portion,
wherein the first pixel circuit portion comprises one first sub-pixel circuit, one second sub-pixel circuit, and one third sub-pixel circuit.

5. The display panel of claim 4, wherein the one first sub-pixel circuit, the one second sub-pixel circuit, and the one third sub-pixel circuit are electrically connected to the one first sub-pixel, the one second sub-pixel, and the two third sub-pixels, respectively.

6. The display panel of claim 5, wherein the one third sub-pixel circuit is electrically connected to the two third sub-pixels.

7. The display panel of claim 4, further comprising a third pixel portion in the second area, the third pixel portion comprising one first sub-pixel, one second sub-pixel, and one third sub-pixel.

8. The display panel of claim 7, further comprising a second pixel circuit portion in the second area,
wherein the second pixel circuit portion comprises one first sub-pixel circuit, one second sub-pixel circuit, and three third sub-pixel circuits, and
wherein at least one of the first, second, or third sub-pixel circuits in the second pixel circuit portion is electrically connected to the third pixel portion.

9. The display panel of claim 8, further comprising a fourth pixel portion in the second area, the fourth pixel portion comprising one first sub-pixel, one second sub-pixel, and three third sub-pixels.

10. The display panel of claim 9, wherein the one first sub-pixel circuit and the one second sub-pixel circuit of the second pixel circuit portion are electrically connected to the one first sub-pixel and the one second sub-pixel of the third pixel portion, respectively, and
wherein at least one of the three third sub-pixel circuits of the second pixel circuit portion is electrically connected to the one third sub-pixel of the third pixel portion.

11. The display panel of claim 10, wherein the one first sub-pixel circuit, the one second sub-pixel circuit, and the three third sub-pixel circuits of the second pixel circuit portion are electrically connected to the one first sub-pixel, the one second sub-pixel, and the three third sub-pixels of the fourth pixel portion, respectively.

12. The display panel of claim 1, wherein the second pixel portion comprises two first sub-pixels, two second sub-pixels, and four third sub-pixels.

13. The display panel of claim 12, further comprising a third pixel circuit portion in the second area and electrically connected to the second pixel portion, the third pixel circuit portion comprising one first sub-pixel circuit, one second sub-pixel circuit, and two third sub-pixel circuits.

14. The display panel of claim 13, wherein the one first sub-pixel circuit and the one second sub-pixel circuit of the third pixel circuit portion are electrically connected to the two first sub-pixels and the two second sub-pixels of the second pixel portion, respectively, and
wherein the two third sub-pixel circuits of the third pixel circuit portion are electrically connected to two of the third sub-pixels of the second pixel portion, respectively.

15. The display panel of claim 14, further comprising a fifth pixel portion in the second area and on the third pixel circuit portion, the fifth pixel portion comprising one first sub-pixel, one second sub-pixel, and two third sub-pixels.

16. The display panel of claim 15, further comprising a fourth pixel circuit portion in the second area and electrically connected to the fifth pixel portion, the fourth pixel circuit portion comprising one first sub-pixel circuit, one second sub-pixel circuit, and two third sub-pixel circuits.

17. The display panel of claim 16, further comprising a sixth pixel portion in the second area and on the fourth pixel circuit portion, the sixth pixel portion comprising one first sub-pixel, one second sub-pixel, and two third sub-pixels.

18. The display panel of claim 17, wherein the one first sub-pixel circuit, the one second sub-pixel circuit, and the two third sub-pixel circuits of the fourth pixel circuit portion are electrically connected to the one first sub-pixel, the one second sub-pixel, and the two third sub-pixels of the fifth pixel portion, respectively.

19. The display panel of claim 18, wherein the one first sub-pixel circuit, the one second sub-pixel circuit, and the two third sub-pixel circuits of the fourth pixel circuit portion are electrically connected to the one first sub-pixel, the one second sub-pixel, and the two third sub-pixels of the sixth pixel portion, respectively.

20. A display apparatus comprising:
a display panel comprising:
a substrate having a first area, a second area extending at least partially around a periphery of the first area, and a third area extending at least partially around a periphery of the second area;
a first pixel portion in a portion of the first area that is adjacent to a boundary between the first area and the second area; and
a second pixel portion nearer to a central portion of the first area than the first pixel portion is, a number of sub-pixels in the first pixel portion being less than a number of sub-pixels in the second pixel portion; and
a component below the display panel and overlapping the first area.
